(19) United States
(12) Patent Application Publication
(10) Pub. No.: US 2011/0304044 A1
(43) Pub. Date: Dec. 15, 2011

(54) STACKED CHIP PACKAGE STRUCTURE AND ITS FABRICATION METHOD

(76) Inventor: Ming-hong LIN, Hsinchu (TW)

(21) Appl. No.: 12/831,693

(22) Filed: Jul. 7, 2010

(30) Foreign Application Priority Data
Jun. 15, 2010 (TW) 099119432

(51) Int. Cl. H01L 23/498; H01L 21/98

(52) U.S. Cl. 257/738; 438/109; 257/E23.069; 257/E21.705

(57) ABSTRACT

A stacked chip package structure includes: a first chip and a second chip stacked on a substrate; a first electrical connection structure electrically connecting the substrate and the first chip; and a second electrical connection structure electrically connecting the second chip and the first chip, wherein the second electrical connection structure, disposed on a third chip, includes an adhesive layer encapsulating a second solder ball structure on the second chip and a first solder ball structure on the first chip; and a plurality of conductive wires disposed in the adhesive layer for conducting the second solder ball structure and the first solder ball structure. A fabrication method for the stacked chip package structure is also disclosed. Forming conductive wires in the adhesive layer electrically connecting the upper and lower chips may improve potential problems caused when using wire bonding technology for the upper chip during stacking of the multilayer chips.

### BACKGROUND OF THE INVENTION

1. Field of the Invention

The present invention is related to a stacked chip package structure and its fabrication method, and more particularly to a stacked chip package structure promoting yield and its fabrication method.

2. Description of the Prior Art

Because of the increasing demand on the miniaturization and the operation speed of the electronic products and therefore the growing demand on the functionality and capacity of a single semiconductor package, multichip module, where two or more semiconductor chips are combined in a single package structure to reduce the volume of the whole circuit structure of the electronic product and enhance the electrical property, has become a trend. That is, by combining two or more chips in a single package structure, multichip package structure push forward the limit of the operation speed. The signal delay and the access time of the multichip package structure are decreased by the reduced interconnection length between the chips.

In the prior stacked chip package technology, a plurality of chips are stacked vertically on a substrate with an active side of each chip facing toward the same direction. Each chip is electrically connected to the substrate and the inter-chip connection is achieved by bond wires. However, due to the diameter and the bending capability of the bond wire, thicker chips are often required to provide enough room for the bond wires. With the growing demand on a lighter, slimmer, shorter and smaller electronic devices presently or in the future, the thickness of the package body has to be decreased, and the chips will be progressively thinned. Therefore, stacking technology for thinned chips becomes a key issue for packaging.

### SUMMARY OF THE INVENTION

The present invention is directed to providing a stacked chip package structure and its fabrication method which, by forming a plurality of conductive wires in replacement of the bond wires in an adhesive layer to achieve interconnection between the upper and lower chips, effectively improves the potential problem caused when using wire bonding technology for the upper chip during stacking of the multilayer chips.

According an embodiment, a stacked chip package structure includes: a substrate, a first chip, a first electrical connection structure, a second chip, a third chip, and a second electrical connection structure. The first chip is disposed on the substrate. The first electrical connection structure electrically connects the substrate and the first chip, wherein the first electrical connection structure includes: at least two first solder ball structures stacked on the contact of the first chip; and a bond wire extending upward from the contact of the substrate to a position between the first solder ball structures. The second chip is stacked on the first chip with the position of the first electrical connection structure exposed, and a second solder ball structure is disposed on the contact of the second chip. The third chip is stacked on the second chip, wherein the second electrical connection is disposed on the lower surface of the third chip, electrically connecting the first chip and the second chip. The second electrical connection structure includes: an adhesive layer disposed on the lower surface of the third chip, wherein the adhesive layer encapsulates the second solder ball structure and the first solder ball structure on the top; and a plurality of conductive wires disposed in the adhesive layer, wherein an end of each conductive wire is connected to the second solder ball, and the other end is connected to the first solder ball encapsulated by the adhesive layer.

According to an embodiment, a fabrication method for a stacked chip package structure includes the following steps. A substrate is provided. A first chip and a second chip are stacked on the substrate with a portion of the first chip exposed. A first electrical connecting step is performed for electrically connecting the substrate and the first chip, wherein the first electrical connecting step includes: forming a first solder ball structure on the contact of the first chip; connecting the contact of the substrate to the first solder ball structure with a bond wire; and forming another of the first solder ball structure on the first solder ball structure, so that an end of the bond wire is compressed between the first solder ball structure and the other of the solder ball structure. A second solder ball structure is formed on the second chip. And a second electrical connection step is performed for electrically connecting the second chip and the first chip, wherein the second electrical connecting step includes: providing a third chip, underneath which a second electrical connection structure is disposed, wherein the second electrical connection structure includes an adhesive layer and a plurality of conductive wires disposed therein; stacking a third chip on the second chip, wherein the adhesive layer encapsulates the second solder ball structure and the first solder ball structure on the top; and connecting an end of each conductive wire to the second solder ball structure and the other end to the first solder ball structure encapsulated by adhesive layer.

The objective, technologies, features and advantages of the present invention will become more apparent from the following description in conjunction with the accompanying drawings, wherein certain embodiments of the present invention are set forth by way of illustration and examples.

### BRIEF DESCRIPTION OF THE DRAWINGS

FIG. 1, FIG. 2, and FIG. 3 are cross-sectional diagrams illustrating the structure of the stacked chip package structure and its fabrication method according to an embodiment of the present invention; and

FIG. 4 and FIG. 5 are cross-sectional diagrams illustrating the structure of the stacked chip package structure and its fabrication method according to another embodiment of the present invention.

### DESCRIPTION OF THE PREFERRED EMBODIMENT

The detail description is provided below. The best mode embodiment presented is for the purpose of illustration and description, and should not be used to limit the present invention.

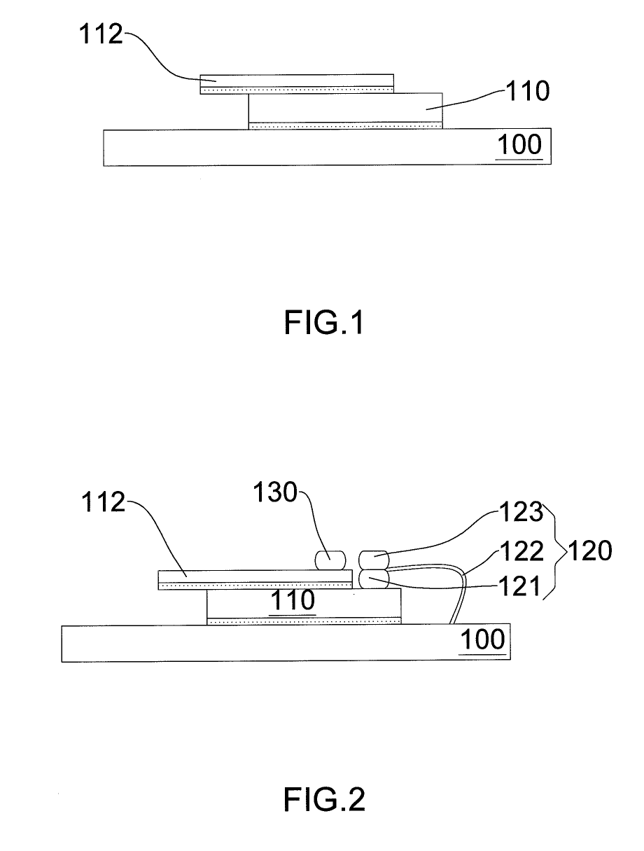

The fabrication method of the stacked chip package structure according to an embodiment is depicted in FIG. 1, FIG. 2 and FIG. 3. First, referring to FIG. 1, a substrate 100 is provided. Next, a first chip 110 and a second chip 112 are stacked on the substrate 100 in sequence, and a portion of the first chip 110 is exposed. In this embodiment, the first chip 110 and the second chip 112 are stacked in a staircase manner. Then, referring to FIG. 2, performing a first electrical connecting step where a first electrical connection structure 120 electrically connecting the substrate 100 and the first chip 110 is formed. The first electrical connecting step includes: forming a first solder ball structure 121 on the contact of the first chip 110; connecting the contact on the substrate 100 and the first solder ball structure 121 with a bond wire 122; and forming another of the first solder ball structure 123 on the solder ball structure 121 so that an end of the bond wire 122 is compressed between the first solder ball structure 121 and another of the first solder ball structure 123. According to an embodiment, a reverse bonding technology is applied in the first electrical connecting step. Referring still to FIG. 2, a second solder ball structure 130 is formed on the second chip 112.

Continuing the above description, as illustrated in FIG. 3, a second electrical connecting step is performed to electrically connect the second chip 112 and the first chip 110. The second electrical connecting step includes: providing a third chip 114, underneath which a second electrical connection structure 140 is disposed, wherein the second electrical connection structure 140 includes an adhesive layer 131 and a plurality of conductive wires 142 disposed in the adhesive layer 141. Next, the third chip 114 is stacked on the second chip 112, and the second solder ball structure 130 and the first solder ball structure on the top, such as the first solder ball structure 123, are encapsulated by the adhesive layer 141. Then, an end of each conductive wire 142 is connected to the second solder ball structure 130, and the other end is connected to the first solder ball structure 123 encapsulated by the adhesive layer 141 to finish connecting the first chip 110 and the second chip 112 electrically.

Continuing the above description, in the present embodiment, the second electrical connection structure 140 is directly disposed on the lower surface of the third chip 114. When the third chip 114 is stacked on the second chip 112, the second electrical connection structure 140 conducts the solder ball structures on the second chip 112 and the first chip 110. It can be understood that the second electrical connection structure 140, connecting the first chip 110 and the second chip 112 electrically, can also be formed on the second chip 112 directly in an appropriate way, and then the third chip 114 is disposed on the adhesive layer 141.

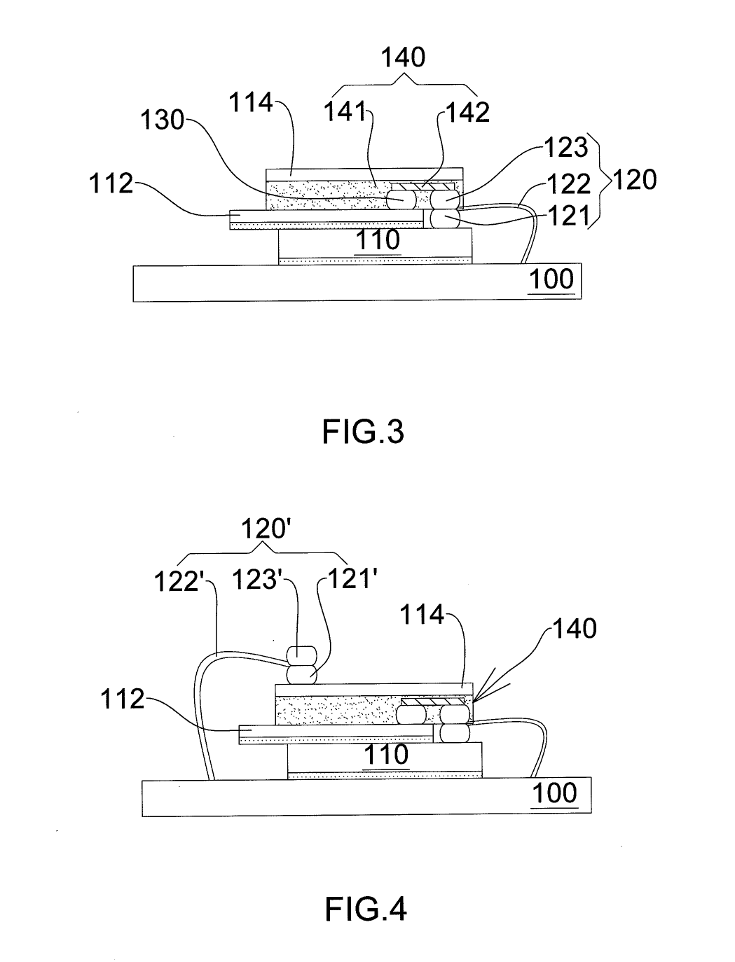

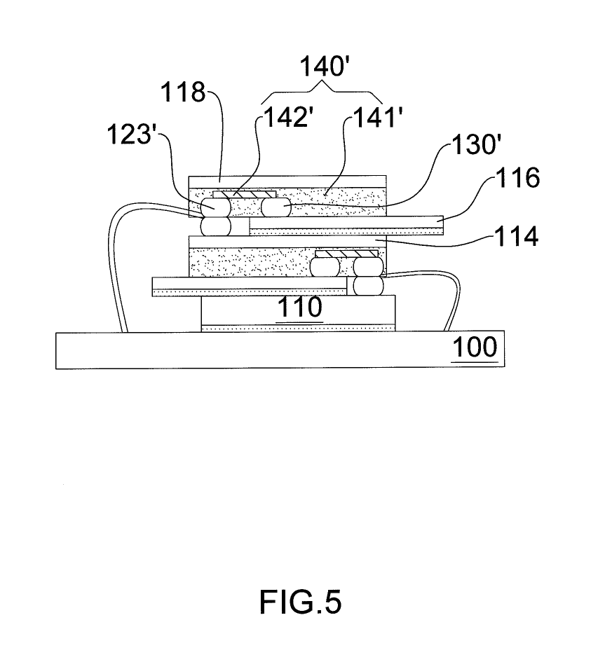

Continuing the above discussion, referring still to FIG. 4, the fabrication method of the stacked chip package structure according to an embodiment further includes performing a third electrical connecting step for forming a third electrical connection structure 120′ electrically connecting the substrate 100 and the third chip 114, wherein the third electrical connection structure 120′ can have the same structure as the first electrical connection structure 120 (as shown in FIG. 2). By the same token, according to an embodiment as illustrated in FIG. 5, a fourth chip 116 can be disposed on the third chip 113, and a fourth electrical connection structure 140′, similar to the second connection structure 120, electrically connecting the third chip 113 and the fourth chip 114 can be formed to produce a stacked chip package structure of more layers. The fabrication method of the present invention can be applied to a stacked structure with a plurality of thin chips (e.g. thickness<50 nm). By using the conductive leads (i.e. the conductive wires) disposed in the adhesive layer of the upper chip as the electrical connection bridging the upper chip and the lower chip, the problem caused by using wire bonding technology directly for the upper chip may be improved. Besides, the fabrication method of the present invention may promote product yield.

Referring to FIG. 3, the stacked chip package structure according to an embodiment includes: a substrate 100, a first chip 110, a first electrical connection structure 120, a second chip 112, a third chip 114 and a second electrical connection structure 140. The first chip 110 is disposed on the substrate 100. The first electrical connection structure 120 electrically connects the substrate 100 and the first chip 110, wherein the first electrical connection structure 120 includes at least two first solder ball structures 121, 123 stacked on the contact of the first chip 110; and a bond wire 122 extends upward from the contact on the substrate 100 to a position between the first solder ball structures 121, 123. The second chip 112 is stacked on the first chip 110 with the position of the first electrical connection structure 120 exposed, and a second solder ball structure 130 is disposed on the contact of the second chip 112. As shown in the figure, the first chip 110 and the second chip are stacked in a staircase manner. Additionally, each of the lower surfaces of the first chip 110 and the second chip 112 further has an insulation layer or an adhesive layer disposed thereon, respectively for affixing the first chip 110 on the substrate 100, and the second chip 112 on the first chip 110. The third chip 114 is disposed on the second chip 112, wherein the second electrical connection structure 140 is disposed on the lower surface of the third chip 114, and electrically connects the first chip 110 and the second chip 112. The second electrical connection structure 140 includes: an adhesive layer 141 disposed on the lower surface of the third chip 114, and encapsulating the second solder ball structure 130 and the first solder ball structure 123 on the top; and a plurality of conductive wires 142 disposed in the adhesive layer 141. An end of each conductive wire 142 is connected to the second solder ball structure 130, and the other end of each conductive wire 142 is connected to the first solder ball structure 123 encapsulated by the adhesive layer 141.

Continuing the above description, in another embodiment in reference to FIG. 4, the stacked chip package structure further includes a third electrical connection structure 120′ (including at least two first solder ball structures 121′, 123′ and a bond wire 122′) electrically connecting the substrate 100 and the third chip 114, wherein the third electrical connection structure 120′ and the first electrical connection structure 120 (as shown in FIG. 2) has the same structure. It can be understood that in an embodiment as shown in FIG. 5, a fourth chip 116 with a fourth solder ball structure 130′ is stacked on the third chip 114 in a staircase manner. As the stacking structure and the electrical connection arrangement of the first chip 110 and the second chip 112, a fourth electrical connection structure 140′ (including an adhesive layer 141′ and a plurality of conductive wires 142′) is disposed on the lower surface of a fifth chip 118 for electrically connecting the third chip 114 and the fourth chip 116, and thereby achieving a stacked chip package structure of more layers. The stacked chip package structure of the present invention may effectively reduce the use of bond wires, allowing the electrical connection between the upper chip and the lower chip achieved without considering the issue of the bond wires and the thickness of the chips. Such advantage not only simplifies the process, but also promotes the stacking capacity of a package and the product yield post process.

In summary, a stacked chip package structure and its fabrication method according to an embodiment of the present invention, by forming conductive wires in replacement of bond wires in an adhesive layer to achieve the interconnection between the upper and the lower chips, effectively improves the potential problems caused when the wire bonding technology is used for the upper chip during stacking of the multilayer chips.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A stacked chip package structure comprising:
a substrate;
a first chip disposed on the substrate;
a first electrical connection structure electrically connecting the substrate and the first chip, wherein the first electrical connection structure comprises:
at least two first solder ball structures disposed on the contact of the first chip; and
a bond wire extends upward from the contact of the substrate to a position between the first solder ball structures;
a second chip stacked on the first chip with the position of the first electrical connection structure exposed, and a second solder ball structure disposed on the contact of the second chip; and
a third chip disposed on the second chip, wherein a second electrical connection structure is disposed on the lower surface of the third chip, and electrically connects the first chip and the second chip, and the second electrical connection structure comprises:
an adhesive layer disposed on the lower surface of the third chip, wherein the adhesive layer encapsulates the second solder balls and the first solder balls on the top; and
a plurality of conductive wires disposed in the adhesive layer, wherein an end of each conductive wire is connected to the second solder ball structure, and the other end of each conductive wire is connected to the first solder ball structure encapsulated by the adhesive layer.

2. The stacked chip package structure according to claim 1, further comprises a third electrical connection structure electrically connecting the substrate and the third chip, wherein the third electrical connection structure has the same structure as the first electrical connection structure.

3. The stacked chip package structure according to claim 1, wherein the lower surfaces of the first chip and the second chip each further has an insulation layer or an adhesive layer disposed thereon.

4. The stacked chip package structure according to claim 1, wherein the first chip and the second chip are stacked in a staircase manner.

5. A fabrication method of a stacked chip package structure comprises:
providing a substrate;
stacking a first chip and a second chip on the substrate in sequence with a portion of the first substrate exposed;
performing a first electrical connecting step for forming a first electrical connection structure electrically connecting the substrate and the first chip, wherein the first electrical connecting step comprises:
forming a first solder ball structure on the contact of the first chip;
connecting the contact of the substrate to the first solder ball structure with a bond wire;
forming another of the first solder ball structure on the first solder ball structure so that an end of the bond wire is compressed between the first solder ball structure and the other of the solder ball structure;
forming a second solder ball structure on the second chip; and
performing a second electrical connecting step for electrically connecting the second chip and the first chip, wherein the second electrical connecting step comprises:
providing a third chip, underneath which a second electrical connection structure is disposed, wherein the second electrical connection structure comprises an adhesive layer and a plurality of conductive wires disposed therein;
stacking the third chip on the second chip, wherein the adhesive layer encapsulates the second solder ball structure and the first solder ball structure on the top; and
connecting an end of each conductive wire to the second solder ball structure and the other end to the first solder ball structure encapsulated by the adhesive layer.

6. The fabrication method of a stacked chip package structure according to claim 5, wherein a reverse bonding technology is applied in the first electrical connecting step.

7. The fabrication method of a stacked chip package structure according to claim 5, further comprises performing a third electrical connecting step for forming a third electrical connection structure electrically connecting the substrate and the third chip, wherein the third electrical connection structure has the same structure as the first electrical connection structure.

8. The fabrication method of a stacked chip package structure according to claim 5, wherein the first chip and the second chip are stacked in a staircase manner.
